(19) United States
(12) Patent Application Publication
(10) Pub. No.: US 2003/0169583 A1
(43) Pub. Date: Sep. 11, 2003

(54) Shielding structure suitable for use with transmitter-receivers

(75) Inventor: Yoshikiyo Watanabe, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/379,203

(22) Filed: Mar. 4, 2003

(30) Foreign Application Priority Data
Mar. 6, 2002 (JP) 2002-059698

(51) Int. Cl. H05K 9/00

(52) U.S. Cl. 361/818

(57) ABSTRACT

In a shielding structure according to the present invention, a first cover for a first circuit and a second cover for a second circuit have lower ends of two opposing side plates connected by a connecting section, the connecting section and the lower ends of the side plates being soldered to a circuit board. Accordingly, the covers may be integrated with the circuit board only once, thus providing an easy assembly and reducing cost.

### BACKGROUND OF THE INVENTION

1. Field of the Invention

The present invention relates to a shielding structure suitable for use with transmitter-receivers and so on of mobile phones.

2. Description of the Related Art

Related-art shielding structures will be described as an example of the application to transmitter-receivers.

FIG. 3 is a plan view of a related-art shielding structure and FIG. 4 is a cross sectional view of essential parts of the related-art shielding structure.

The arrangement of the related-art shielding structure will be described with reference to FIGS. 3 and 4. A circuit board 51 formed of a multilayer substrate and having a wiring pattern (not shown) includes a first and second area 52 and 53 which are divided from each other, such that the first area 52 has an electrical component 54 to form a first circuit 55 such as transmit-receive switching circuit, and the second area 53 has an electrical component 56 to form a second circuit 57 such as a transmitting-receiving circuit.

The circuit board 51 has a plurality of cuts 51a and 51b in two opposing sides thereof, and has holes 51c and 51d, which are apart from each other, at substantially the center thereof.

A box-shaped first cover 58 formed by bending a metallic plate includes a rectangular upper plate 58a, four side plates 58b formed by being bent downward vertically from the four sides of the upper plate 58a, and protrusions 58c that project downward from the lower ends of the two opposing side plates 58b.

The first cover 58 is arranged such that the protrusions 58c are inserted into the cuts 51a and the holes 51c while covering the first circuit 55.

A box-shaped second cover 59 formed by bending a metallic plate includes a rectangular upper plate 59a, four side plates 59b formed by being bent downward vertically from the four sides of the upper plate 59a, and protrusions 59c that project downward from the lower ends of the two opposing side plates 59b.

The second cover 59 is arranged such that the protrusions 59c are inserted into the cuts 51b and the holes 51d while covering the second circuit 57.

The first and second covers 58 and 59 are soldered to the circuit board 51 by applying reflow solder 60 between the entire area of the lower ends of the respective side plates 58b and 59b of the first and second covers 58 and 59, respectively, and the circuit board 51, with the first and second covers 58 and 59 placed on the circuit board 51.

For manufacturing the first and second covers 58 and 59, a first jig having a rectangular hole and a second jig having a rectangular protrusion that protrudes from the base are prepared, which are not shown. When the upper plate is pressed into the hole of the first jig by the protrusion of the second jig, with the upper plate of the cover positioned at the hole, the side plates are bent along the hole to form a box-shaped cover.

The protrusion of the second jig used for manufacturing, however, has the same thickness from the base to the end, thus, the protrusion is easily broken, and accordingly, long-term use is not possible which increases manufacturing cost.

In the related-art shielding structure, since the first and second covers 58 and 59 are individually assembled, it is troublesome and increases cost.

Also, since the first and second covers 58 and 59 are engaged in the holes 51c and 51d, the spaces therebetween are large, thus increasing the size.

In addition, since the side plates 58b and 59b are bent vertically from the upper plates 58a and 59a, respectively, a lot of space is required to facilitate checking of the solder 60 between the first and second covers 58 and 59, thus posing a problem of increasing the size.

### SUMMARY OF THE INVENTION

Accordingly, it is an object of the present invention to provide a low-cost and compact shielding structure which is easily assembled.

According to the present invention, a shielding structure is provided which comprises a circuit board having mutually divided first and second areas each having an electrical component to form a first circuit and a second circuit; and a first cover and a second cover soldered to the circuit board so as to cover each of the first and second circuits, wherein each of the first and second covers has an upper plate and side plates which are bent downward from the upper plate, wherein the lower ends of two opposing side plates of the first and second covers are connected by a connecting section, and wherein the connecting section and the lower parts of the side plates are soldered to the circuit board.

According to the present invention, preferably, the connecting section has holes, from which the solder is exposed.

According to the present invention, preferably, the side plates of the first and second covers are inclined so as to become wider from the upper plate toward the open side of the side plates.

### BRIEF DESCRIPTION OF THE DRAWINGS

FIG. 1 is a plan view of a shielding structure according to the present invention;

FIG. 2 is a cross sectional view of the shielding structure according to the present invention;

FIG. 3 is a plan view of a related-art shielding structure; and

FIG. 4 is a cross sectional view of the related-art shielding structure.

### DESCRIPTION OF THE PREFERRED EMBODIMENTS

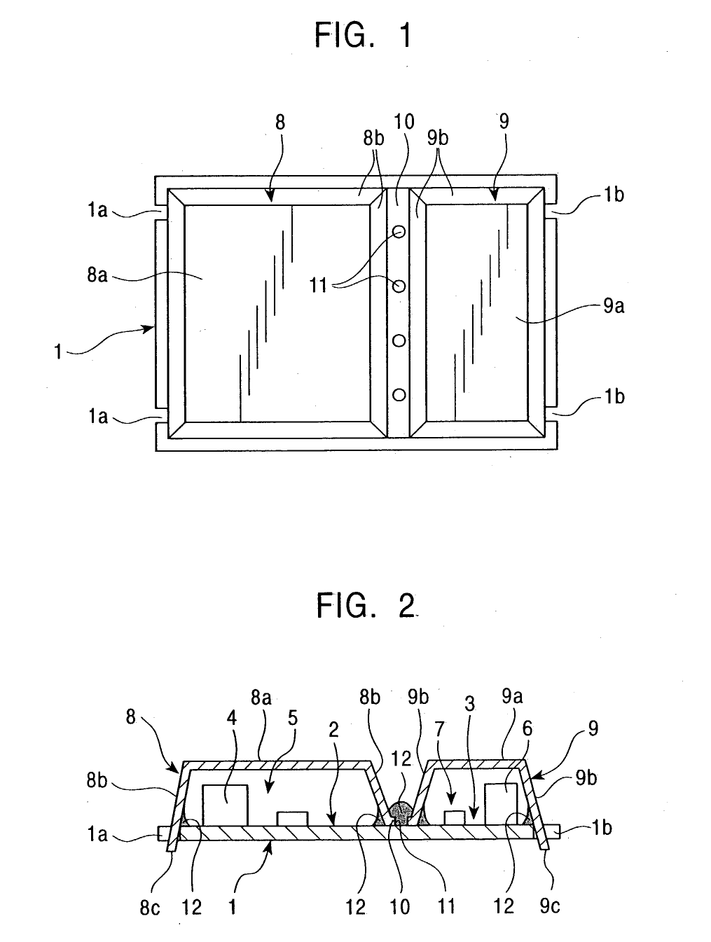

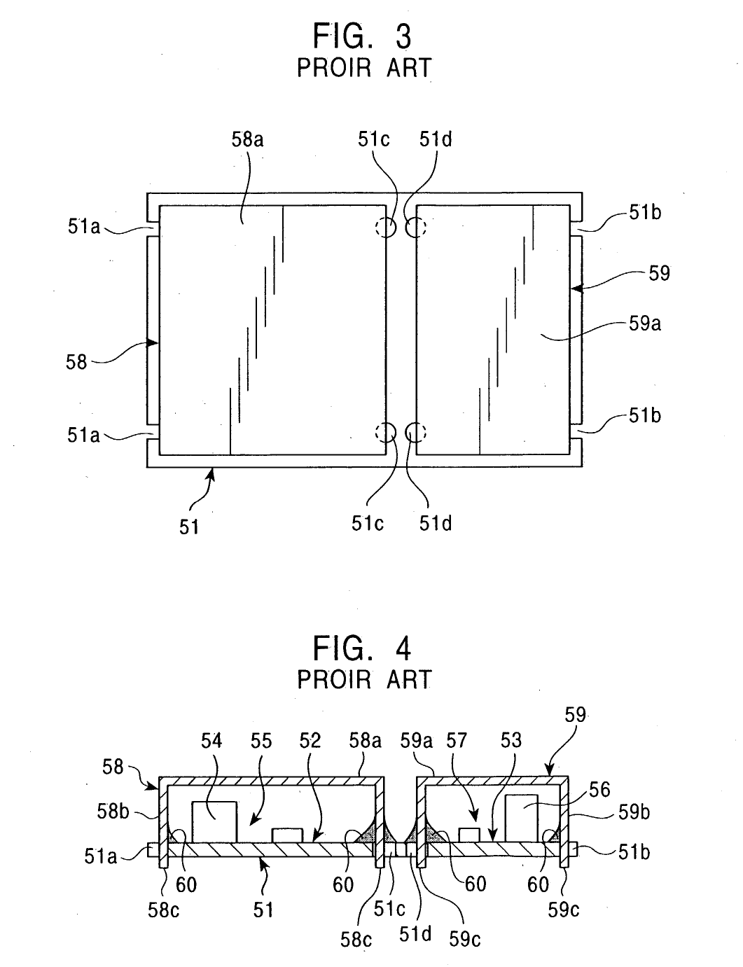

A shielding structure according to the present invention will be described as an example of an application to transmitter-receivers. FIG. 1 is a plan view of the shielding structure according to the present invention and FIG. 2 is a cross sectional view of the shielding structure according to the present invention.

The arrangement of the shielding structure according to the present invention will be described with reference to FIGS. 1 and 2. A circuit board 1 formed of a multilayer substrate and having a wiring pattern (not shown) includes first and second areas 2 and 3 which are divided from each other, wherein the first area 2 has an electrical component 4 to form a first circuit 5 such as a transmit-receive switching circuit, and the second area 3 has an electrical component 6 to form a second circuit 7 such as a transmitting-receiving circuit.

The circuit board 1 has a plurality of cuts 1a and 1b in two opposing sides thereof.

A box-shaped first cover 8 formed by bending a metallic plate includes a rectangular upper plate 8a, four side plates 8b formed by being bent downward at an angle from four sides of the upper plate 8a, and protrusions 8c that project downward from the lower end of one of the side plates 8b.

The side plates 8b of the first cover 8 are inclined so as to become wider from the upper plate 8a toward the open side that is the free ends of the side plates 8b.

A box-shaped second cover 9 formed by bending a metallic plate includes a rectangular upper plate 9a, four side plates 9b formed by being bent downward at an angle from four sides of the upper plate 9a, and protrusions 9c that project downward from the lower end of one of the side plates 9b.

The side plates 9b of the second cover 9 are inclined so as to become wider from the upper plate 9a toward the open side that is the free ends of the side plates 9b.

The first and second covers 8 and 9 are integrated with each other by a flat-shaped connecting section 10 that connects the lower ends of the two opposing side plates 8b and 9b, the connecting section 10 having a plurality of holes 11.

The connected first and second covers 8 and 9 are positioned such that the protrusions 8c and 9c are inserted into the cuts 1a and 1b while covering the first and second circuits 5 and 7, respectively.

The first and second covers 8 and 9 are soldered to the circuit board 1 by applying reflow solder 12 between the entire area of the lower ends of the respective side plates 8b and 9b of the first and second covers 8 and 9 and the circuit board 1, with the first and second covers 8 and 9 placed on the circuit board 1.

When the solder 12 is applied, it is exposed from the top of the holes 11 to allow a visual check of the solder 12 between the first and second covers 8 and 9, also, since the side plates 8b and 9b of the first and second covers 8 and 9 are inclined, the space therebetween on the upper sides (upper plates) is large, thus allowing a visual check to be easily performed.

For manufacturing the first and second covers 8 and 9, a first jig having a rectangular hole and a second jig having a pyramid-shaped protrusion that protrudes from the base are prepared, which are not shown. When the upper plate is pressed into the hole of the first jig by the protrusion of the second jig, with the upper plate of the cover positioned at the hole, the side plates are bent along the hole to form a box-shaped cover having the inclined side plates.

The pyramid-shaped protrusion of the second jig used for manufacturing, however, is shaped to be thick at the base and to be gradually decreased in thickness toward the end, thus, the protrusion is rarely broken, and accordingly, the allowed long-term use reduces manufacturing cost.

Although the connecting section of the embodiment has a flat shape, it may have a V shape formed from the lower ends of the adjacent side plates.

The shielding structure according to the present invention comprises a circuit board having mutually divided first and second areas each having an electrical component to form a first circuit and a second circuit; and a first cover and a second cover soldered to the circuit board so as to cover each of the first and second circuits, wherein each of the first and second covers has an upper plate and side plates which are bent downward from the upper plate, wherein the lower ends of the two opposing side plates of the first and second covers are connected by a connecting section, and wherein the connecting section and the lower parts of the side plates are soldered to the circuit board. Consequently, the covers may be integrated with the circuit board only once, thus providing an easily assembling process and reducing cost.

Also, the circuit board of the present invention requires no holes for engagement of the first and second covers as in related art, thus reducing the size.

The connecting section has holes, from which the solder is exposed, thus facilitating a visual check for soldering.

The side plates of the first and second covers are inclined so as to become wider from the upper plate toward the open side of the side plates. Accordingly, the upper side can be widened while the space between the lower ends of the first and second covers is kept small, to allow miniaturization and to facilitate a visual check for soldering.

For manufacturing the covers, the protrusion of the jig for forming the side plates by bending can be formed in the shape of a pyramid, thus increasing the life of the jig and reducing cost.

What is claimed is:

1. A shielding structure comprising: a circuit board having mutually divided first and second areas each having an electrical component to form a first circuit and a second circuit; and a first cover and a second cover soldered to the circuit board so as to cover each of the first and second circuits, respectively, wherein each of the first and second covers has an upper plate and side plates which are bent downward from the upper plate, wherein the lower ends of two opposing side plates of the first and second covers are connected by a connecting section, and wherein the connecting section and the lower parts of the side plates are soldered to the circuit board.

2. A shielding structure according to claim 1, wherein the connecting section has holes, from which the solder is exposed.

3. A shielding structure according to claim 1, wherein the side plates of the first and second covers are inclined so as to become wider from the upper plate toward the open side of the side plates.
